(19) United States
(12) Patent Application Publication
(10) Pub. No.: US 2023/0317399 A1
(43) Pub. Date: Oct. 5, 2023

(54) Charged Particle Beam Device

(71) Applicant: Hitachi High-Tech Corporation, Tokyo (JP)

(72) Inventors: Toshimasa KAMEDA, Tokyo (JP); Tomoyo SASAKI, Tokyo (JP); Shunsuke MIZUTANI, Tokyo (JP)

(21) Appl. No.: 18/128,405

(22) Filed: Mar. 30, 2023

(30) Foreign Application Priority Data
Mar. 31, 2022 (JP) 2022-060084

(51) Int. Cl. H01J 37/04

(52) U.S. Cl. CPC H01J 37/045; H01J 2237/24528

(57) ABSTRACT

The invention is directed to suppress charge of a region of interest or damage in the region of interest caused by blanking. A charged particle beam device includes: a deflector configured to scan a region of interest with a beam emitted from a beam source; a second deflector configured to retract the beam to outside of the region of interest after scanning the region of interest with the beam; and one or more computer systems including one or more processors configured to execute a program stored in a storage medium, in which the one or more computer systems determine a retraction direction or a retraction position of the beam (Step S402) based on a scanning direction of the beam in the region.

### TECHNICAL FIELD

The present disclosure relates to a charged particle beam device and particularly relates to a charged particle beam device that can retract a charged particle beam to a retraction region.

### BACKGROUND ART

A system that scans a sample surface with a charged particle beam to execute observation, length measurement, inspection, analysis, and the like of the sample is known. In this system, in order to suppress unnecessary irradiation of the sample with a charged particle beam, an electron beam is retracted from the sample by largely deflecting the charged particle beam using an electric field or a magnetic field to irradiate an aperture plate or the like with the charged particle beam. This function is called blanking.

PTL 1 discloses a charged particle beam device that performs blanking. In the charged particle beam device described in PTL 1, the occurrence of axis deviation or the like is suppressed by changing a blanking direction for each scanning line of a charged particle beam to balance charging between a plurality of directions.

### CITATION LIST

### Patent Literature

PTL 1: JP2013-254673A

### SUMMARY OF INVENTION

### Technical Problem

However, PTL 1 does not describe a relationship between a blanking direction and a scanning region. That is, in PTL 1, when a scanning region is present in a blanking direction, a charged particle beam during blanking crosses a length measurement point such that the scanning region is charged. As a result, due to the charging of the scanning region, it is difficult to accurately measure the length measurement point. In particular, a primary beam that is accelerated at a low acceleration voltage (for example, 100 V) is largely affected by charging caused by blanking.

In addition, when the charged particle beam during blanking crosses the scanning region, damage (shrink) occurs in the scanning region. In particular, in measurement of a fine pattern of a semiconductor device that is manufactured using a microfabrication technique by EUV, the damage (shrink) in the scanning region needs to be minimized.

Accordingly, the present disclosure provides a charged particle beam device that can suppress charging of a scanning region (region of interest) or damage in the region of interest caused by blanking.

### Solution to Problem

A charged particle beam device according the present disclosure includes: a first deflector configured to scan a region of interest with a beam emitted from a beam source; a second deflector configured to retract the beam to outside of the region of interest after scanning the region of interest with the beam; and one or more computer systems including one or more processors configured to execute a program stored in a storage medium, in which the one or more computer systems (i) determine a retraction direction or a retraction position of the beam or (ii) output characteristic information regarding the retraction direction or the retraction position of the beam based on a scanning direction of the beam in the region of interest.

### Advantageous Effects of Invention

According to the present disclosure, charge of a region of interest or damage in the region of interest caused by blanking can be suppressed.

### BRIEF DESCRIPTION OF DRAWINGS

FIG. 1A is a schematic configuration diagram illustrating a charged particle beam device according to a first embodiment.

FIG. 1B is a hardware block diagram illustrating a computer system according to the first embodiment.

FIG. 2 is a diagram illustrating a blanking direction and an irradiation trajectory of a charged particle beam in the first embodiment.

FIGS. 3A to 3D are diagrams illustrating a relationship between a scanning direction of a charged particle beam and a blanking direction in the first embodiment.

FIG. 4 is a flowchart illustrating a determination process of a blanking direction in the first embodiment.

FIG. 5 is a diagram illustrating a relationship between a scanning direction of a charged particle beam and a blanking direction in a second embodiment.

FIG. 6 is a diagram illustrating a relationship between a scanning direction of a charged particle beam and a blanking direction in a third embodiment.

FIG. 7 is a flowchart illustrating an optimization process of the blanking direction in the third embodiment.

FIG. 8 is a diagram illustrating a processing order of a plurality of scanning regions A1 to A12 in a fourth embodiment.

FIG. 9 is a flowchart illustrating a determination process of the processing order of the plurality of scanning regions in the fourth embodiment.

FIGS. 10A and 10B are diagrams illustrating a processing order of a plurality of scanning regions in a fifth embodiment.

FIG. 11 is a flowchart illustrating an optimization process of the processing order of the plurality of scanning regions in the fifth embodiment.

FIGS. 12A and 12B are diagrams illustrating a processing order of a plurality of scanning regions in a sixth embodiment.

FIGS. 13A and 13B is a diagram illustrating a processing order of a plurality of scanning regions on a wafer in the sixth embodiment.

FIG. 14 is a flowchart illustrating an adjustment process of the processing order of the plurality of scanning regions in the sixth embodiment.

FIGS. 15A to 15D are diagrams illustrating a positional relationship between a previous irradiation region and a scanning region in a seventh embodiment.

FIG. 16 is a flowchart illustrating a determination process of a blanking direction in the seventh embodiment.

FIG. 17 is a diagram illustrating a positional relationship between a previous irradiation region and a scanning region in an eighth embodiment.

FIG. 18 is a flowchart illustrating an optimization process of the blanking direction in the eighth embodiment.

FIGS. 19A and 19B are diagrams illustrating a positional relationship between a previous irradiation region and a scanning region in a ninth embodiment.

FIG. 20 is a flowchart illustrating a determination process of the previous irradiation region in the ninth embodiment.

FIGS. 21A and 21B is a diagram illustrating a positional relationship between a previous irradiation region and a scanning region in a tenth embodiment.

FIG. 22 is a flowchart illustrating an optimization process of the previous irradiation region in the tenth embodiment.

FIG. 23 is a flowchart illustrating a process of determining whether or not to perform blanking in an eleventh embodiment.

FIG. 24 is a diagram illustrating a relationship between an irradiation time of a sample with a charged particle beam and a charge amount of the sample in a twelfth embodiment.

FIG. 25 is a flowchart illustrating an optimization process of a blanking direction in the twelfth embodiment.

FIG. 26 is a flowchart illustrating an optimization process of a previous irradiation region in the twelfth embodiment.

### DESCRIPTION OF EMBODIMENTS

Embodiments of the present disclosure will be described in detail based on the drawings. In the following embodiments, it goes without saying that the components (including element steps and the like) are not necessarily required, unless expressly stated otherwise and unless they are considered to be clearly required in principle or other reasons.

### First Embodiment

(Charged Particle Beam Device 100)

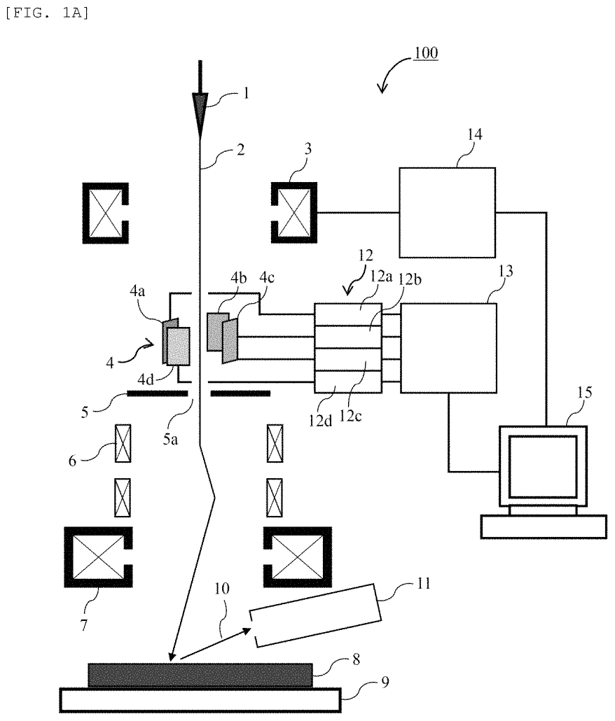

FIG. 1A is a schematic configuration diagram illustrating a charged particle beam device according to a first embodiment. In the first embodiment, the charged particle beam device that retracts or blocks (hereinafter, appropriately referred to as “blanking”) a charged particle beam for each scanning line will be described. Blanking may be performed for each frame or may be performed for each pixel.

As illustrated in FIG. 1A, the charged particle beam device 100 includes an electron gun 1 that is a beam source of a charged particle beam 2, a convergence lens 3, a blanking deflector (second deflector) 4, an aperture plate 5, an image shift deflector (first deflector) 6, an objective lens 7, a stage 9, a detector 11, a blanking voltage application device 12, a blanking voltage control device 13, a convergence lens control device 14, and a computer system 15.

The charged particle beam (primary beam) 2 emitted from the electron gun 1 passes through an aperture 5a of the aperture plate 5 due to a convergence action by a magnetic field of the convergence lens 3. The charged particle beam 2 passed through the aperture 5a is deflected to scan a sample 8 placed on the stage 9 due to an electric field or a magnetic field of the image shift deflector 6, and is focused on the sample 8 due to a convergence action by a magnetic field of the objective lens 7. Secondary electrons 10 generated from the sample 8 by the irradiation of the charged particle beam 2 are detected by the detector 11. As a result, an enlarged image of a scanning region of the charged particle beam 2 on the sample 8 is obtained.

In order to minimize damage of the sample 8 by the irradiation of the charged particle beam 2, it is necessary to prevent the charged particle beam 2 from being scattered on the sample 8 as far as possible. Accordingly, in the charged particle beam device 100, blanking is performed between lines, between frames, and between pixels. When blanking of the charged particle beam 2 is performed, due to an electric field or a magnetic field of the blanking deflector 4, the charged particle beam 2 is largely deflected to the outside (for example, on the aperture plate 5) of a region of interest positioned outside the sample 8.

The blanking deflector 4 includes four electrodes 4a to 4d, and four drive circuits 12a to 12d of the blanking voltage application device 12 apply voltages to the four electrodes 4a to 4d, respectively. Magnitudes, directions, and timings of the voltages applied by the four drive circuits 12a to 12d are controlled by the blanking voltage control device 13. Under the control of the blanking voltage control device 13, an electric field having a given magnitude and a given direction can be formed at a given timing. The number of electrodes in the blanking deflector 4 and the number of drive circuits in the blanking voltage application device 12 are not limited to four. During blanking, the charged particle beam 2 is deflected in a direction of an electric field of the blanking deflector 4 and is blocked by the aperture plate 5. The blanking voltage control device 13 receives blanking control information from the computer system 15, and controls operations of the four drive circuits 12a to 12d based on the blanking control information. The blanking control information includes a direction (hereinafter, referred to as “blanking retraction direction”) in which the charged particle beam 2 is retracted from the scanning region that is scanned with the charged particle beam 2 to a retraction region, a direction (hereinafter, referred to as “blanking release direction”) in which the charged particle beam 2 enters from the retraction region to the scanning region, and timing information representing a timing of blanking.

(Computer System 15)

FIG. 1B is a hardware block diagram illustrating the computer system according to the first embodiment. The details of the computer system 15 according to the first embodiment will be described with reference to FIG. 1B. The computer system 15 executes each of processes of a flowchart described below. The computer system 15 includes a processor 151, a main storage unit 152, an auxiliary storage unit 153, an input/output interface (hereinafter, the interface will be abbreviated as “I/F”) 154, a communication I/F 155, a display unit 156, and a bus 157 through which the respective modules are communicably connected to each other.

The processor 151 is a central processing unit. The processor 151 is, for example, a CPU (Central Processing Unit), a DSP (Digital Signal Processor), or an ASIC (Application Specific Integrated Circuit). The processor 151 loads a program stored in the auxiliary storage unit 153 to a work area of the main storage unit 152 such that the program is executable in the work area, and executes the loaded program. The main storage unit 152 stores a program to be executed by the processor 151, data to be processed by the processor, and the like. The main storage unit 152 is a flash memory, a RAM (Random Access Memory), or the like. The auxiliary storage unit (storage medium) 153 stores, for example, a program relating to a determination process of the blanking direction. The auxiliary storage unit 153 is, for example, a solid state drive device or a hard disk drive device.

The input/output I/F 154 is communicably connected to the blanking voltage control device 13 and the convergence lens control device 14. The above-described blanking control information is transmitted to the blanking voltage control device 13 through the input/output I/F 154. The communication I/F 155 is an interface for communicable connection to an external device through a network. The display unit 156 displays various information.

The computer system 15 may be an on-premise computer system or may be a cloud computer system. The computer system 15 is configured with one or more computer systems.

(Blanking)

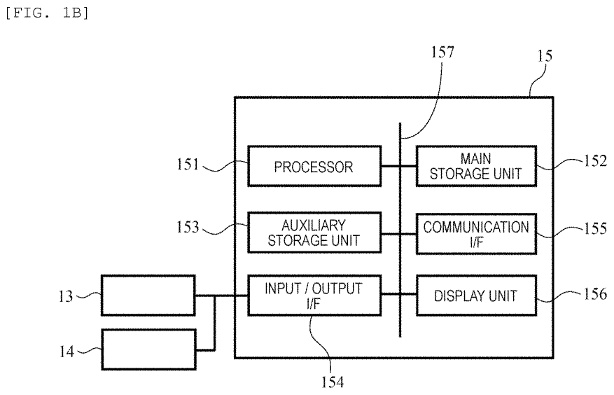

FIG. 2 is a diagram illustrating a blanking direction and an irradiation trajectory of a charged particle beam in the first embodiment. In order to simplify the description, FIG. 2 illustrates the two electrodes 4a and 4c of the blanking deflector 4. FIG. 2 illustrates a positional relationship between the electrodes 4a and 4c of the blanking deflector 4, a scanning region (a region of interest, a length measurement region, or an inspection region) A that is scanned with the charged particle beam 2, and a blanking irradiation region B that is irradiated with the charged particle beam 2 during blanking.

First, due to an electric field by the blanking deflector 4, the charged particle beam 2 is deflected in a blanking release direction BLK1 from a retraction region C (on the aperture plate 5) to the scanning region A. The charged particle beam 2 is deflected to scan the scanning region A in a scanning direction S due to an electric field or a magnetic field of the image shift deflector 6. In the process of scanning the scanning region A, the charged particle beam 2 is deflected in a blanking retraction direction BLK2 from the scanning region A to the retraction region C due to an electric field by the blanking deflector 4.

(Relationship Between Scanning Direction and Blanking Direction)

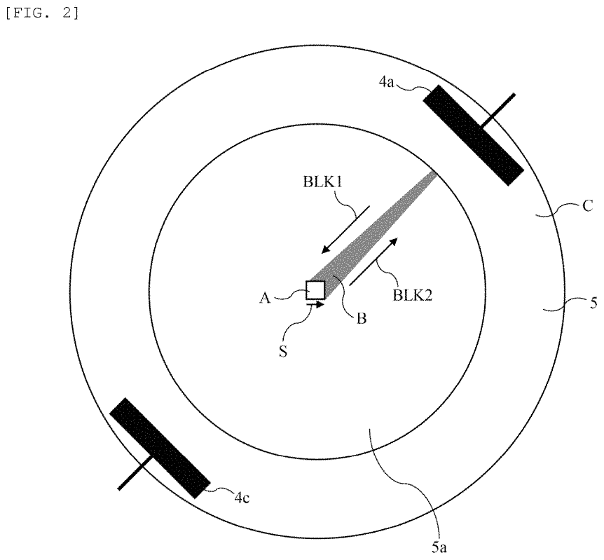

FIGS. 3A to 3D are diagrams illustrating a relationship between a scanning direction of a charged particle beam and a blanking direction in the first embodiment. A relationship between the scanning direction S of the charged particle beam 2 and the blanking direction (the blanking retraction direction BLK2, the blanking release direction BLK1) will be described with reference to FIGS. 3A to 3D.

In the first embodiment, the blanking direction or the blanking position is automatically determined based on the scanning direction S to prevent the charged particle beam 2 from crossing a subsequent scanning region (non-scanning region) during blanking. In addition, in the first embodiment, the blanking direction or the blanking position may be automatically determined based on the scanning direction S such that a region other than the non-scanning region in the scanning region A is irradiated with the charged particle beam 2 during the blanking of the charged particle beam 2. As illustrated in FIG. 3A, when the scanning direction S of the charged particle beam 2 in the scanning region A is the +X direction, the blanking release direction BLK1 is the −Y direction, and the blanking retraction direction BLK2 is the +Y direction. In addition, as illustrated in FIG. 3B, when the scanning direction S of the charged particle beam 2 in the scanning region A is the −Y direction, the blanking release direction BLK1 is the −X direction, and the blanking retraction direction BLK2 is the +X direction. In addition, as illustrated in FIG. 3C, when the scanning direction S of the charged particle beam 2 in the scanning region A is the −X direction, the blanking release direction BLK1 is the +Y direction, and the blanking retraction direction BLK2 is the −Y direction. In addition, as illustrated in FIG. 3D, when the scanning direction S of the charged particle beam 2 in the scanning region A is the +Y direction, the blanking release direction BLK1 is the +X direction, and the blanking retraction direction BLK2 is the −X direction.

In addition, in the first embodiment, the charged particle beam 2 is deflected for scanning in the scanning direction S multiple times in order from the closest to the retraction position of the charged particle beam 2. That is, a traveling direction T of scanning in the scanning region A travels in a direction (blanking release direction BLK1) opposite to the blanking retraction direction BLK2. For example, in the first embodiment, as illustrated in FIG. 3A, first scanning (No. 1), second scanning (No. 2), third scanning (No. 3), and fourth scanning (No. 4) are sequentially executed in the −Y direction in the scanning region A.

The blanking direction and the blanking position may be determined based on the traveling direction T of scanning in the scanning region A.

(Determination Process of Blanking Direction)

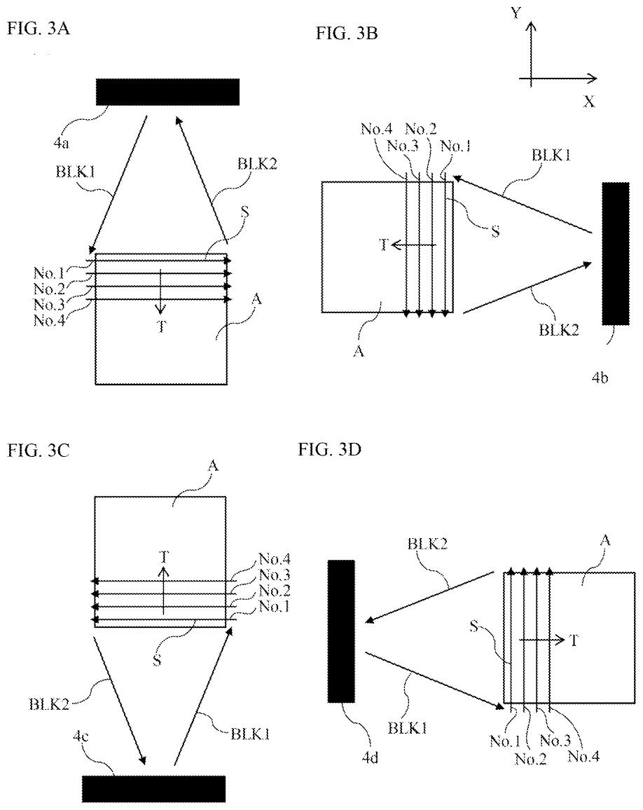

FIG. 4 is a flowchart illustrating a determination process of the blanking direction in the first embodiment. Each of steps in the flowchart of FIG. 4 is executed by the processor 151 executing the program relating to the determination process of the blanking direction that is stored in the auxiliary storage unit 153.

The computer system 15 acquires a position of the scanning region A and the scanning direction S of the charged particle beam 2 in the scanning region A from recipe information including scanning conditions, procedure, and the like of the scanning region A (Step S401). The position of the scanning region A refers to a position of a pattern that is a processing object or a position of a FOV (field of view) including the processing object. Next, the computer system 15 determines the blanking direction or the blanking position based on the scanning direction S of the charged particle beam 2 in the scanning region A (Step S402). For example, in the computer system 15, a direction that is rotated clockwise by about 90° with respect to the scanning direction S is the blanking release direction BLK1, and a direction that is rotated counterclockwise by about 90° with respect to the scanning direction S is the blanking retraction direction BLK2.

The computer system 15 may determine a blanking direction based on the scanning direction S and the traveling direction T of scanning in the scanning region A. Further, the computer system 15 may cause the display unit 156 or another display unit that is communicably connected to the computer system 15 to display information regarding the blanking direction or the blanking position.

### Effect of First Embodiment

In the first embodiment, the blanking direction or the blanking position can be determined based on the scanning direction S of the charged particle beam 2 in the scanning region A. Thus, the charged particle beam 2 during blanking can be prevented from crossing the non-scanning region in the scanning region A. As a result, charging of the scanning region or damage of the scanning region caused by blanking can be prevented.

In the first embodiment, the charged particle beam 2 is deflected for scanning in the scanning direction S multiple times in order from the closest to the retraction position. Thus, the charged particle beam 2 during blanking can be prevented from crossing the non-scanning region in the scanning region A.

### Second Embodiment

In the first embodiment, the charged particle beam 2 that is retracted in the blanking retraction direction BLK2 is moved in the blanking release direction BLK1 from the retraction position to a start position of the next scanning. On the other hand, in a second embodiment, the charged particle beam 2 that is retracted in the blanking retraction direction BLK2 passes the outside of the scanning region from the retraction position, is moved to a release position, and is moved in the blanking release direction BLK1 from the release position to the start position of the next scanning.

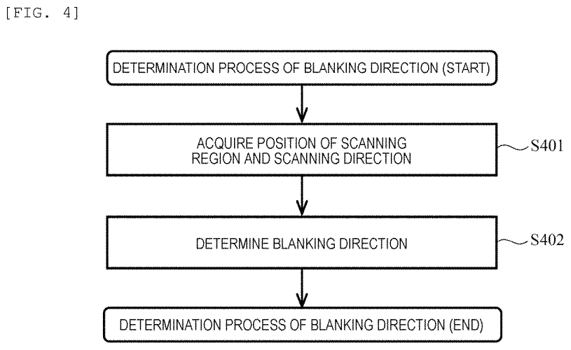

FIG. 5 is a diagram illustrating a relationship between a scanning direction of a charged particle beam and a blanking direction in the second embodiment. A relationship between the scanning direction S and the blanking direction (the blanking release direction BLK1, the blanking retraction direction BLK2, a blanking movement direction BLK3) in the second embodiment will be described with reference to FIG. 5.

The charged particle beam 2 is deflected to scan the scanning region A in the scanning direction S due to an electric field or a magnetic field of the image shift deflector 6. The charged particle beam 2 is deflected in a blanking retraction direction BLK2 from the scanning region A to the retraction region C due to an electric field by the blanking deflector 4. The charged particle beam 2 that is deflected to the retraction position adjacent to the electrode 4a is deflected on the aperture plate 5 in the blanking movement direction BLK3 to the release position adjacent to the electrode 4d. Due to an electric field by the blanking deflector 4, the charged particle beam 2 is deflected in the blanking release direction BLK1 from the release position adjacent to the electrode 4d to the start position of the next scanning.

### Effect of Second Embodiment

In the second embodiment, the retraction position of blanking and the release position of blanking can be made different from each other. Therefore, the degree of freedom for the blanking retraction direction BLK2 and the blanking release direction BLK1 can be increased. As a result, the blanking retraction direction BLK2 and the blanking release direction BLK1 can be easily determined to prevent the charged particle beam 2 during blanking from crossing the subsequent scanning region. The other effects are the same as the other embodiments.

### Third Embodiment

In the first embodiment, the blanking direction and the blanking position are determined based on the scanning direction S of the charged particle beam 2 in the scanning region A. In a third embodiment, whether or not the charged particle beam 2 crosses a subsequent scanning region during blanking is determined to change the blanking direction and the blanking position.

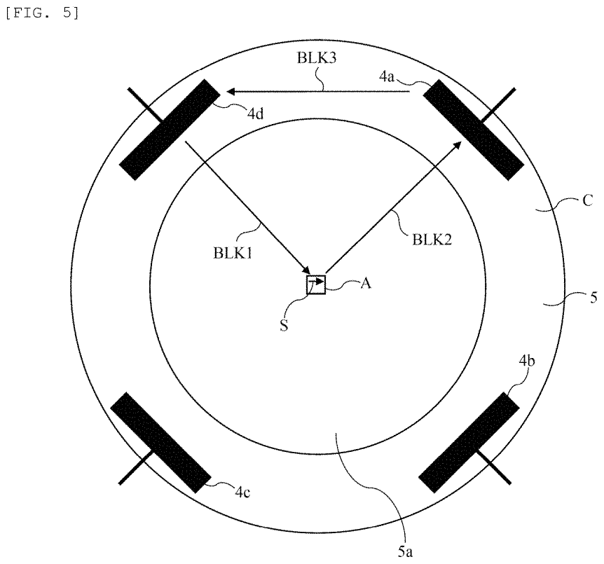

FIG. 6 is a diagram illustrating a relationship between a scanning direction of a charged particle beam and a blanking direction in the third embodiment. In the third embodiment, whether or not the charged particle beam 2 crosses a subsequent scanning region during blanking is determined to change the blanking direction or the blanking position. In the third embodiment, the blanking direction or the blanking position is determined such that a region other than the non-scanning region in the scanning region A is irradiated with the charged particle beam 2 during the blanking of the charged particle beam 2. As illustrated in FIG. 6, due to an electric field by the blanking deflector 4, the charged particle beam 2 is deflected in the blanking release direction BLK1 from the retraction region to the scanning region A. The charged particle beam 2 is deflected to scan the scanning region A in the scanning direction S (+X direction) due to an electric field or a magnetic field of the image shift deflector 6. The charged particle beam 2 is deflected in the blanking retraction direction BLK2 from the scanning region A to the retraction region due to an electric field by the blanking deflector 4.

However, the charged particle beam 2 that is deflected in the blanking retraction direction BLK2 crosses a subsequent scanning region (non-scanning region) U of the scanning region A. In this case, the subsequent scanning region (non-scanning region) U is charged or damaged by the charged particle beam 2 during blanking. Accordingly, in the third embodiment, the blanking direction and the blanking position are changed to prevent the charged particle beam 2 from crossing the subsequent scanning region (non-scanning region) U during blanking. For example, in the example of FIG. 6, the blanking release direction BLK1 is changed from the +X direction to the −Y direction, and the blanking retraction direction BLK2 is changed from the −X direction to the +Y direction. That is, the changed blanking release direction BLK1′ is the −Y direction, and the changed blanking retraction direction BLK2′ is the +Y direction.

(Optimization Process of Blanking Direction)

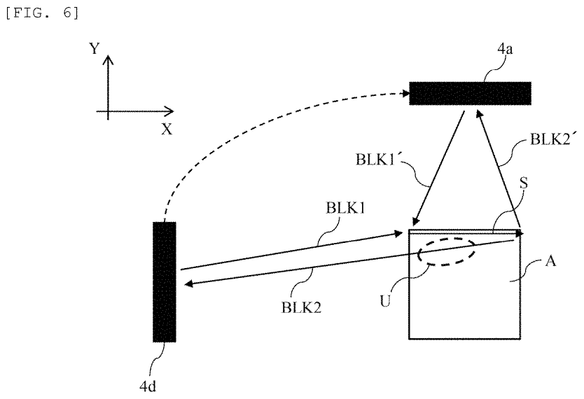

FIG. 7 is a flowchart illustrating an optimization process of the blanking direction in the third embodiment. Each of steps in the flowchart of FIG. 7 is executed by the processor 151 executing a program relating to an optimization process of the blanking direction that is stored in the auxiliary storage unit 153.

The computer system 15 acquires the blanking direction before change, the position of the scanning region A, and the scanning direction S of the charged particle beam 2 in the scanning region A (Step S701). Next, the computer system 15 determines whether or not the charged particle beam 2 during blanking crosses the subsequent scanning region (non-scanning region) U based on the blanking direction, the position of the scanning region A, and the scanning direction S that are acquired (Step S702). When the computer system 15 determines that the charged particle beam 2 during blanking crosses the subsequent scanning region (non-scanning region) U (Step S702: Yes), the computer system 15 changes the blanking direction to prevent the charged particle beam 2 during blanking from crossing the subsequent scanning region (non-scanning region) U (Step S703). When the computer system 15 determines that the charged particle beam 2 during blanking does not cross the subsequent scanning region (non-scanning region) U (Step S702: No), the computer system 15 ends the present process without changing the blanking direction.

Step S703 may be a step of rotating the blanking direction by a predetermined angle (for example, 90°). In this case, the computer system 15 executes the determination of Step 702 again, and determines whether or not the charged particle beam 2 during blanking after rotating crosses the subsequent scanning region (non-scanning region) U. The blanking direction may be repeatedly changed by a predetermined angle until the computer system 15 determines that the charged particle beam 2 during blanking after rotating does not cross the subsequent scanning region (non-scanning region) U.

The computer system 15 may cause the display unit 156 or another display unit that is communicably connected to the computer system 15 to display characteristic information regarding the blanking direction or the blanking position. The characteristic information includes, for example, a message representing that the charged particle beam 2 during blanking crosses the scanning region and a message urging to change the blanking direction.

### Effect of Third Embodiment

In the third embodiment, in Step S702, the computer system 15 determines whether or not the charged particle beam 2 during blanking crosses the subsequent scanning region (non-scanning region) U. Therefore, the charged particle beam 2 during blanking can be reliably prevented from crossing the subsequent scanning region (non-scanning region) U. The other effects are the same as the other embodiments.

### Fourth Embodiment

In a fourth embodiment, an example of scanning a plurality of scanning regions A1 to A12 will be described. In the fourth embodiment, the order of processes (for example, observation, length measurement, inspection, analysis, and the like) of the plurality of scanning regions A1 to A12 is determined to prevent the charged particle beam 2 during blanking from crossing the subsequent scanning region. In the fourth embodiment, the processing order of the plurality of scanning regions A1 to A12 is determined such that regions other than non-scanning regions in the plurality of scanning regions A1 to A12 are irradiated with the charged particle beam 2 during blanking.

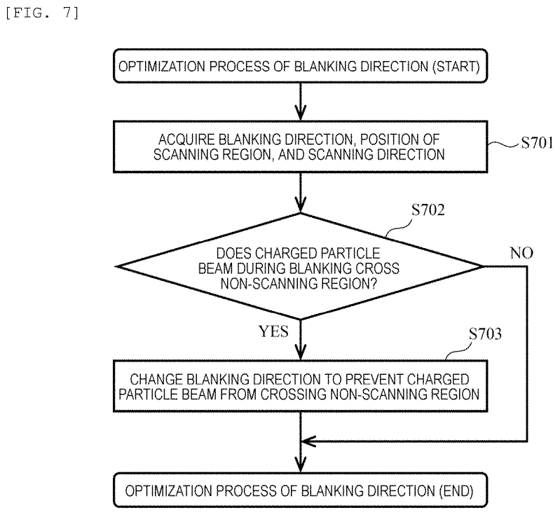

FIG. 8 is a diagram illustrating the processing order of the plurality of scanning regions A1 to A12 in the fourth embodiment. The processing order of the plurality of scanning regions A1 to A12 in the fourth embodiment will be described with reference to FIG. 8. In order to simplify the description, in FIG. 8, all of the scanning directions S of the plurality of scanning regions A1 to A12 are the same. In the fourth embodiment, the processing order of the plurality of scanning regions A1 to A12 is determined based on first information regarding each of positions of the plurality of scanning regions A1 to A12 and second information regarding the retraction position of the charged particle beam 2. The positions of the scanning regions A1 to A12 include a position of a pattern that is a measuring object or a position of a FOV including the measuring object. In addition, the second information includes the retraction position of the charged particle beam 2 or the retraction direction of the charged particle beam 2.

First, as described in the first embodiment, a blanking direction is determined based on the scanning direction S. The distance from the retraction position in the blanking retraction direction BLK2 to each of the scanning regions A1 to A12 is calculated to determine the processing order of the plurality of scanning regions A1 to A12. In the example of FIG. 8, the scanning regions A10, A11, A12, A7, A8, A9, A4, A5, A6, A1, A2, and A3 are disposed in order from the closest to the retraction position. Therefore, in the example of FIG. 8, the plurality of scanning regions A1 to A12 are processed in order of the scanning regions A10, A11, A12, A7, A8, A9, A4, A5, A6, A1, A2, and A3. The numbers in FIG. 8 represent the processing order.

(Determination Process of Processing Order of Plurality of Scanning Regions)

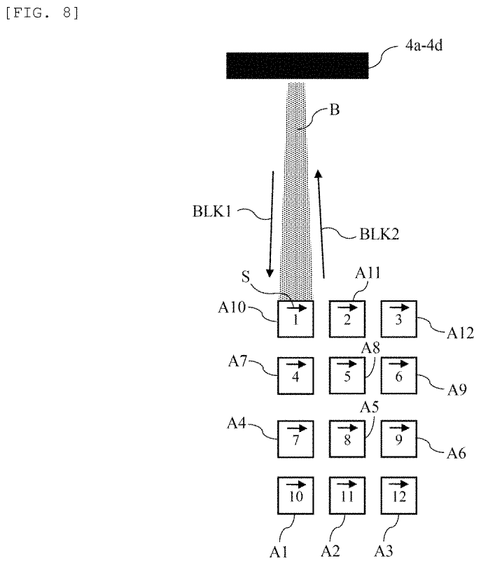

FIG. 9 is a flowchart illustrating a determination process of the processing order of the plurality of scanning regions in the fourth embodiment. Each of steps in the flowchart is executed by the processor 151 executing a program relating to the determination process of the processing order of the plurality of scanning regions that is stored in the auxiliary storage unit 153.

The computer system 15 acquires position information regarding the positions of the plurality of scanning regions A1 to A12 and the scanning direction S (Step S901). The position information may be information regarding irradiation positions of the plurality of scanning regions A1 to A12 with the charged particle beam 2. The computer system 15 determines a blanking direction based on the scanning direction S of the plurality of scanning regions A1 to A12 (Step S902). The process of determining the blanking direction is the same as that of the first embodiment. The computer system 15 calculates the distances between the retraction position in the blanking direction (the blanking retraction direction) and the positions of the plurality of scanning regions A1 to A12 (Step S903), and determines the processing order of the plurality of scanning regions A1 to A12 in the order of the calculated distances (Step S904).

The computer system 15 controls the image shift deflector 6 and the blanking deflector 4 such that the plurality of scanning regions A1 to A12 are processed in the determined processing order while reciprocating the charged particle beam 2 between the plurality of scanning regions A1 to A12 and the retraction position.

The computer system 15 may cause the display unit 156 or another display unit that is communicably connected to the computer system 15 to display order information regarding the processing order of the plurality of scanning regions A1 to A12. The order information includes, for example, a message representing that the charged particle beam 2 during blanking crosses the scanning region and a message urging to change the processing order of the plurality of scanning regions A1 to A12.

### Effect of Fourth Embodiment

In the fourth embodiment, the processing order of the plurality of scanning regions A1 to A12 is determined based on the positions of the plurality of scanning regions A1 to A12 and the retraction position of the charged particle beam 2. Due to the blanking in the scanning regions A1 to A12 that are previously processed, the subsequent scanning regions can be prevented from being charged or damaged. The other effects are the same as the other embodiments.

### Fifth Embodiment

In the fourth embodiment, the processing order of the plurality of scanning regions A1 to A12 is determined based on the positions of the plurality of scanning regions A1 to A12 and the scanning direction S. In a fifth embodiment, whether or not the charged particle beam 2 is to cross the subsequent scanning region during blanking is determined to optimize the processing order of the plurality of scanning regions A1 to A12.

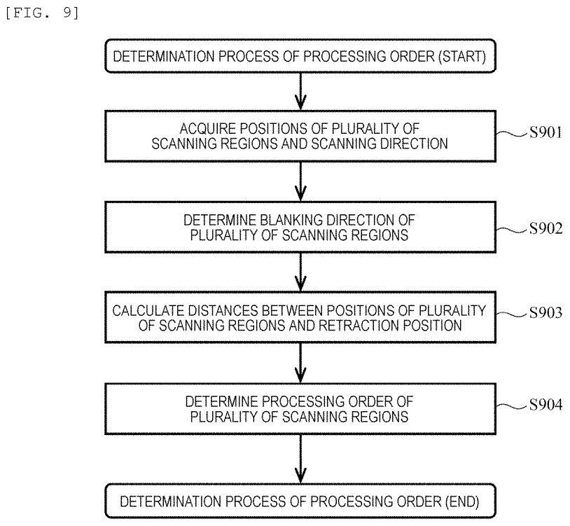

FIGS. 10A and 10B is a diagram illustrating a processing order of a plurality of scanning regions in the fifth embodiment. In a fifth embodiment, whether or not the charged particle beam 2 is to cross the subsequent scanning region during blanking is determined to automatically optimize the processing order of the plurality of scanning regions. As illustrated in FIG. 10A, before the optimization, the plurality of scanning regions A1 to A12 are processed in the processing order. In this case, for example, due to an electric field by the blanking deflector 4, the charged particle beam 2 is deflected in the blanking release direction BLK1 from the retraction position to the scanning region A1. The charged particle beam 2 is deflected to scan the scanning region A1 in a scanning direction S due to an electric field or a magnetic field of the image shift deflector 6. The charged particle beam 2 is deflected in the blanking retraction direction BLK2 from the scanning region A1 to the retraction position due to an electric field by the blanking deflector 4. When the charged particle beam 2 is deflected in the blanking release direction BLK1 to the scanning region A1 and when the charged particle beam 2 is deflected in the blanking retraction direction BLK2 to the retraction position, the charged particle beam 2 crosses the scanning regions A4, A7, and A10 that are processed after the scanning region A1. Therefore, the scanning regions A4, A7, and A10 that are processed after the scanning region A1 are charged or damaged.

Accordingly, in the fifth embodiment, as illustrated in FIG. 10B, after the optimization, the plurality of scanning regions A1 to A12 are processed in order of the scanning regions A10, A11, A12, A7, A8, A9, A4, A5, A6, A1, A2, and A3 that is the order from the closest to the retraction position. The numbers in FIGS. 10A and 10B represent the processing order.

(Optimization Process of Processing Order of Plurality of Scanning Regions)

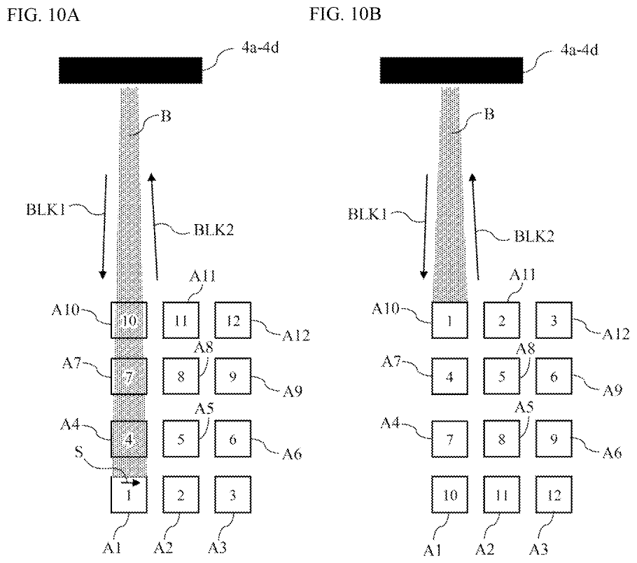

FIG. 11 is a flowchart illustrating an optimization process of the processing order of the plurality of scanning regions in the fifth embodiment. Each of steps in the flowchart is executed by the processor 151 executing a program relating to the optimization process of the processing order of the plurality of scanning regions that is stored in the auxiliary storage unit 153.

The computer system 15 acquires the positions of the plurality of scanning regions A1 to A12, the blanking direction, and the processing order of the plurality of scanning regions A1 to A12 (Step S1101). The computer system 15 determines whether or not the charged particle beam 2 during blanking crosses the subsequent scanning regions A1 to A12 based on the positions of the plurality of scanning regions A1 to A12, the blanking direction, and the processing order of the plurality of scanning regions A1 to A12 that are acquired (Step S1102). When the computer system 15 determines that the charged particle beam 2 during blanking crosses the subsequent scanning regions A1 to A12 (Step S1102: Yes), the computer system 15 changes the processing order of the scanning regions A1 to A12 to prevent the charged particle beam 2 during blanking from crossing the subsequent scanning regions A1 to A12 (Step S1103). When the computer system 15 determines that the charged particle beam 2 during blanking does not cross the subsequent scanning regions A1 to A12 (Step S1102: No), the computer system 15 ends the present process without changing the processing order of the scanning regions A1 to A12.

The computer system 15 may cause the display unit 156 or another display unit that is communicably connected to the computer system 15 to display characteristic information regarding the processing order of the plurality of scanning regions A1 to A12. The characteristic information includes, for example, a message representing that the charged particle beam 2 during blanking crosses the scanning region and a message urging to change the processing order of the plurality of scanning regions A1 to A12.

### Effect of Fifth Embodiment

In the fifth embodiment, in Step S1102, the computer system 15 determines whether or not the charged particle beam 2 during blanking crosses the subsequent subsequent scanning regions A1 to A12. Therefore, the charged particle beam 2 during blanking can be reliably prevented from crossing the subsequent scanning regions A1 to A12. The other effects are the same as the other embodiments.

### Sixth Embodiment

The processing order of the scanning regions A1 to A12 described in the fifth embodiment may be changed based on another standard within a range where there is no influence of the charged particle beam 2 during blanking. For example, in a sixth embodiment, the processing order of the scanning regions A1 to A12 may be adjusted based on a moving distance between the scanning regions A1 to A12 within a range where there is no influence of the charged particle beam 2 during blanking.

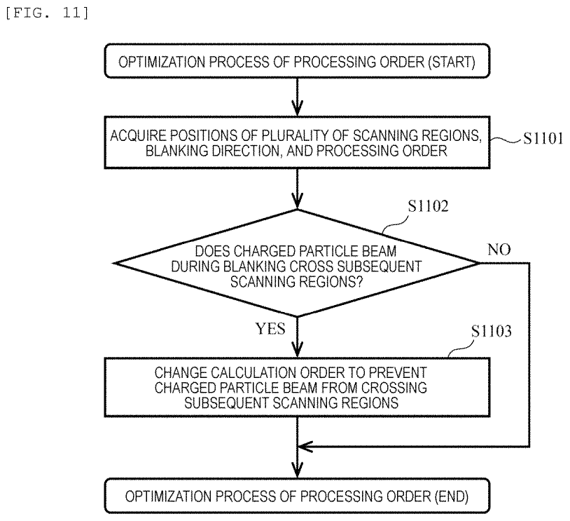

FIGS. 12A and 12B are diagrams illustrating a processing order of a plurality of scanning regions in the sixth embodiment. In the sixth embodiment, the determined or optimized processing order of the scanning regions A1 to A12 is adjusted based on the moving distance of the charged particle beam 2. As illustrated in FIG. 12A, before the optimization, the plurality of scanning regions A1 to A12 are processed in order of the scanning regions A10, A11, A12, A7, A8, A9, A4, A5, A6, A1, A2, and A3. In this case, the subsequent scanning regions A1 to A12 are not affected by the charged particle beam 2 during blanking. For example, by processing the scanning region A7 after the scanning region A12, the moving distance between the scanning regions further increases as compared to when the scanning region A9 is processed after the scanning region A12. As a result, the time required for the measurement also increases.

Accordingly, in the sixth embodiment, as illustrated in FIG. 12B, after the adjustment, the plurality of scanning regions A1 to A12 are processed in order of the scanning regions A10, A11, A12, A9, A8, A7, A4, A5, A6, A3, A2, and A1 based on the moving distance of the charged particle beam 2. The numbers in FIGS. 12A and 12B represent the processing order.

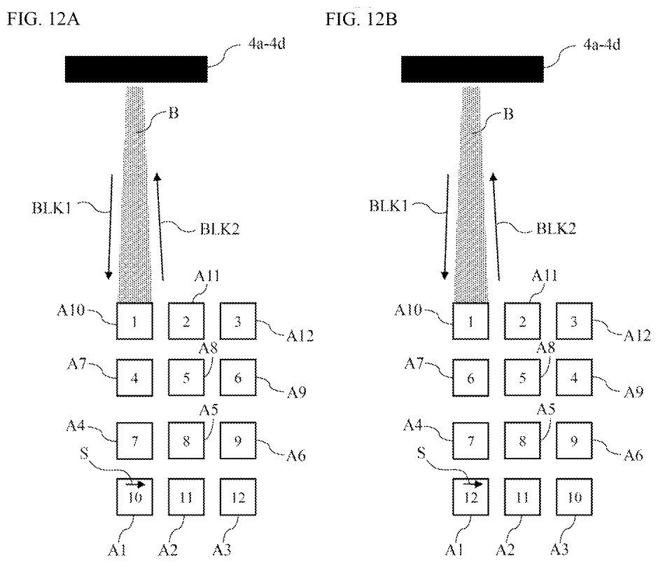

In addition, FIGS. 13A and 13B are diagrams illustrating a processing order of a plurality of scanning regions on a wafer in the sixth embodiment. In the example illustrated in FIGS. 13A and 13B, as in the example of FIGS. 12A and 12B, the determined or optimized processing order of the scanning regions A1 to A11 is adjusted based on the moving distance between the scanning regions A1 to A12. As illustrated in FIG. 13A, before the change, the plurality of scanning regions A1 to A11 on a wafer W are processed in order of the scanning regions A1, A3, A8, A11, A9, A4, A2, A7, A10, A5, and A6. In this case, the subsequent scanning regions A1 to A12 are not affected by the charged particle beam 2 during blanking. For example, by processing the scanning region A3 after the scanning region A1, the moving distance between the scanning regions further increases as compared to when the scanning region A2 is processed after the scanning region A1.

Accordingly, in the sixth embodiment, as illustrated in FIG. 13B, after the adjustment, the plurality of scanning regions A1 to A11 are processed in order of the scanning regions A1, A2, A3, A8, A7, A6, A5, A4, A9, A10, and A11 based on the moving distance of the charged particle beam 2. The numbers in FIGS. 13A and 13B represent the processing order.

(Adjustment Process of Processing Order of Plurality of Scanning Regions)

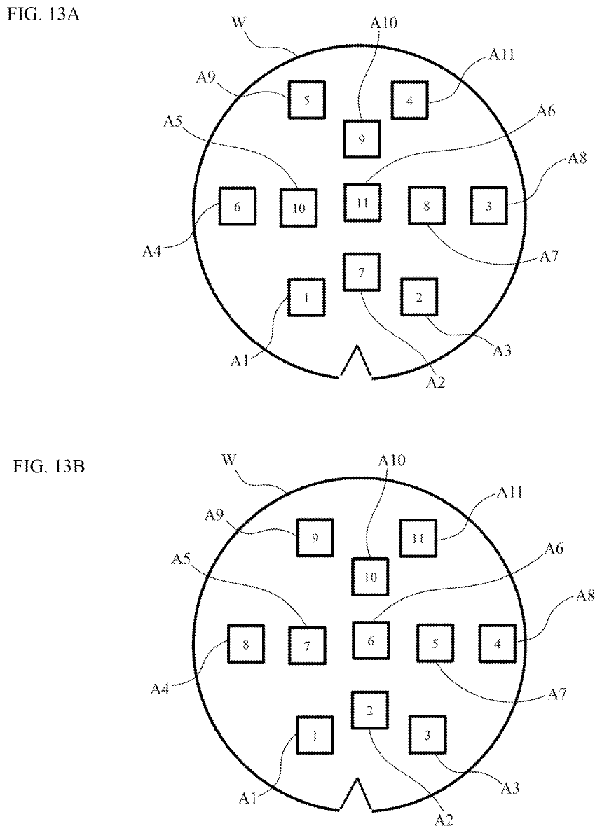

FIG. 14 is a flowchart illustrating an adjustment process of the processing order of the plurality of scanning regions in the sixth embodiment. Each of steps in the flowchart is executed by the processor 151 executing a program relating to the adjustment process of the processing order of the plurality of scanning regions that is stored in the auxiliary storage unit 153.

The computer system 15 executes the processes of Steps S1401 to S1403. Since the contents of Steps S1401 to S1403 are the same as the contents of Steps S1101 to S1103 of FIG. 11, the description thereof will not be repeated. Next, the computer system 15 determines whether or not the moving distance of the charged particle beam 2 is the shortest (Step S1404). When the computer system 15 determines that the moving distance is the shortest (Step S1404: Yes), the computer system 15 ends the process. On the other hand, when the computer system 15 determines that the moving distance is not the shortest (Step S1404: No), the processing order of the scanning regions A1 to A12 is adjusted such that the moving distance of the charged particle beam 2 is the shortest within a range where the charged particle beam 2 during blanking does not cross the subsequent scanning regions A1 to A12 (Step S1405).

The computer system 15 may cause the display unit 156 or another display unit that is communicably connected to the computer system 15 to display characteristic information regarding the processing order of the plurality of scanning regions A1 to A12. The characteristic information includes, for example, a message representing that the moving distance of the charged particle beam 2 is long and a message urging to adjust the processing order of the plurality of scanning regions A1 to A12.

### Effect of Sixth Embodiment

In the sixth embodiment, the processing order of the scanning regions A1 to A12 is adjusted such that the moving distance between the scanning regions A1 to A12 is the shortest. Therefore, the time required until the processes of plurality of scanning regions A1 to A12 are completed can be reduced. The other effects are the same as the other embodiments.

### Seventh Embodiment

In the first to sixth embodiments, the blanking direction or the blanking position is determined and changed to prevent the charged particle beam 2 from crossing the non-scanning region in the scanning region A during blanking before and after scanning the scanning region A, or the processing order of the plurality of scanning regions A1 to A12 is determined and changed to prevent the charged particle beam 2 from crossing the subsequent non-scanning regions of the plurality of scanning regions A1 to A12. In a seventh embodiment, the blanking direction or the blanking position is determined to prevent the charged particle beam 2 from crossing the scanning region A during blanking before and after scanning a previous irradiation region P that is scanned before the scanning region A. The previous irradiation region P is used for auto focus, addressing, or pattern matching.

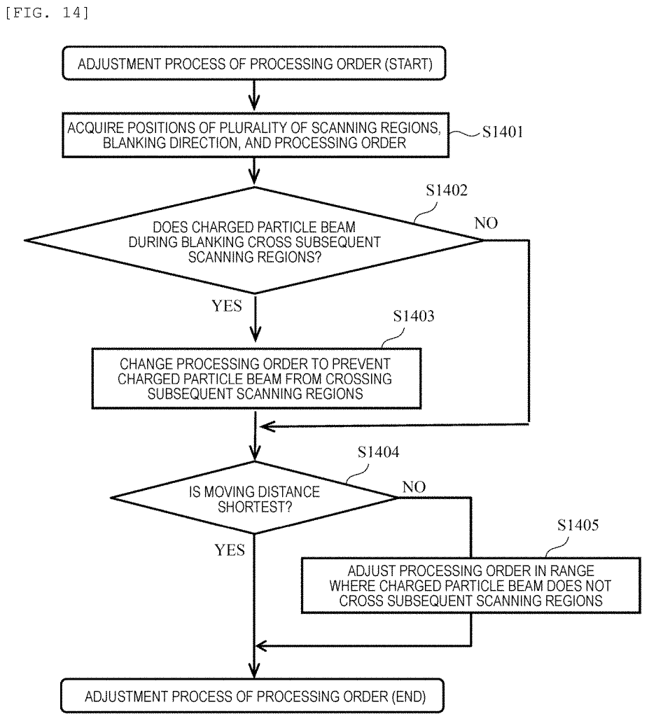

FIGS. 15A to 15D are diagrams illustrating a positional relationship between the previous irradiation region and the scanning region in the seventh embodiment. In the seventh embodiment, the blanking direction and the blanking position before and after scanning the previous irradiation region P are determined based on a position of the previous irradiation region P and the position of the scanning region A. In FIGS. 15A to 15D, in order to simplify the description, scanning directions PS and S of the charged particle beam 2 in the previous irradiation region P and the scanning region A are the +X direction. As illustrated in FIG. 15A, when the previous irradiation region P is disposed on the +X direction side with respect to the scanning region A, in the process of scanning the previous irradiation region P, the blanking release direction BLK1 is the −Y direction, and the blanking retraction direction BLK2 is the +Y direction. In addition, as illustrated in FIG. 15B, when the previous irradiation region P is disposed on the −Y direction side with respect to the scanning region A, in the process of scanning the previous irradiation region P, the blanking release direction BLK1 is the +Y direction, and the blanking retraction direction BLK2 is the −Y direction. In addition, as illustrated in FIG. 15C, when the previous irradiation region P is disposed on the −X direction side with respect to the scanning region A, in the process of scanning the previous irradiation region P, the blanking release direction BLK1 is the −Y direction, and the blanking retraction direction BLK2 is the +Y direction. In addition, as illustrated in FIG. 15D, when the previous irradiation region P is disposed on the +Y direction side with respect to the scanning region A, in the process of scanning the previous irradiation region P, the blanking release direction BLK1 is the −Y direction, and the blanking retraction direction BLK2 is the +Y direction.

(Optimization Process of Blanking Direction)

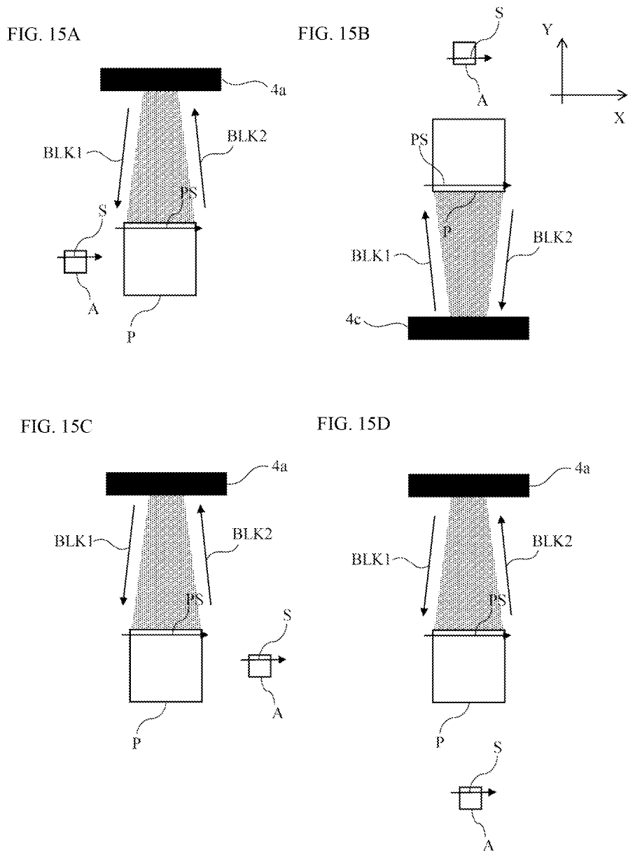

FIG. 16 is a flowchart illustrating a determination process of the blanking direction in the seventh embodiment. Each of steps in the flowchart of FIG. 16 is executed by the processor 151 executing the program relating to the determination process of the blanking direction that is stored in the auxiliary storage unit 153.

The computer system 15 acquires the position of the scanning region A and the position of the previous irradiation region P (Step S1601). Next, the computer system 15 determines the blanking direction or the blanking position in the process of scanning the previous irradiation region P based on the position of the scanning region A and the position of the previous irradiation region P (Step S1602). Next, the computer system 15 may determine the blanking direction or the blanking position in the process of scanning the previous irradiation region P based on the position of the scanning region A, the position of the previous irradiation region P, and the scanning direction PS.

The computer system 15 may cause the display unit 156 or another display unit that is communicably connected to the computer system 15 to display characteristic information regarding the blanking direction or the blanking position. The characteristic information includes, for example, a message representing that the charged particle beam 2 during blanking crosses the scanning region and a message urging to change the blanking direction.

### Effect of Seventh Embodiment

In the seventh embodiment, the blanking direction or the blanking position in the process of scanning the previous irradiation region P can be determined based on the position of the scanning region A and the position of the previous irradiation region P. Thus, the charged particle beam 2 during the blanking can be prevented from crossing the scanning region A. As a result, charging of the scanning region A or damage of the scanning region A caused by blanking can be prevented. The other effects are the same as the other embodiments.

### Eighth Embodiment

In the seventh embodiment, the blanking direction or the blanking position in the process of scanning the previous irradiation region P is determined based on the position of the scanning region A and the position of the previous irradiation region P. In an eighth embodiment, whether or not the charged particle beam 2 crosses the scanning region during blanking in the process of scanning the previous irradiation region P is determined to change the blanking direction and the blanking position.

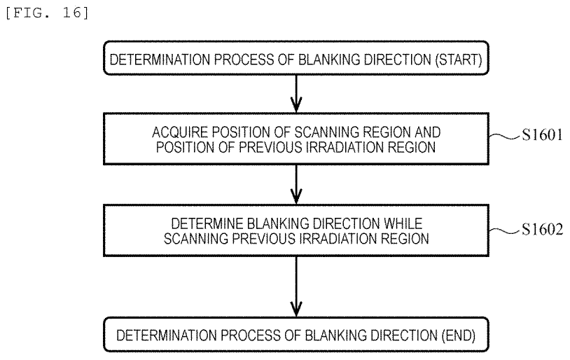

FIG. 17 is a diagram illustrating a positional relationship between the previous irradiation region and the scanning region in the eighth embodiment. In the eighth embodiment, whether or not the charged particle beam 2 crosses the scanning region A during blanking in the process of scanning the previous irradiation region P is determined to change the blanking direction or the blanking position. As illustrated in FIG. 17, due to an electric field by the blanking deflector 4, the charged particle beam 2 is deflected in the blanking release direction BLK1 from the retraction region to the previous irradiation region P. The charged particle beam 2 is deflected to scan the previous irradiation region P in the scanning direction PS (+X direction) due to an electric field or a magnetic field of the image shift deflector 6. The charged particle beam 2 is deflected in the blanking retraction direction BLK2 from the previous irradiation region P to the retraction region due to an electric field by the blanking deflector 4.

However, the charged particle beam 2 that is deflected in the blanking release direction BLK1 and the blanking retraction direction BLK2 crosses the scanning region A that is scanned after scanning the previous irradiation region P. In this case, the scanning region A is charged or damaged by the charged particle beam 2 during blanking. Accordingly, in the eighth embodiment, the blanking direction and the blanking position are changed to prevent the charged particle beam 2 from crossing the scanning region A during blanking. For example, in the example of FIG. 17, the blanking release direction BLK1 is changed from the +X direction to the −Y direction, and the blanking retraction direction BLK2 is changed from the −X direction to the +Y direction. That is, the changed blanking release direction BLK1′ is the −Y direction, and the changed blanking retraction direction BLK2′ is the +Y direction.

(Optimization Process of Blanking Direction)

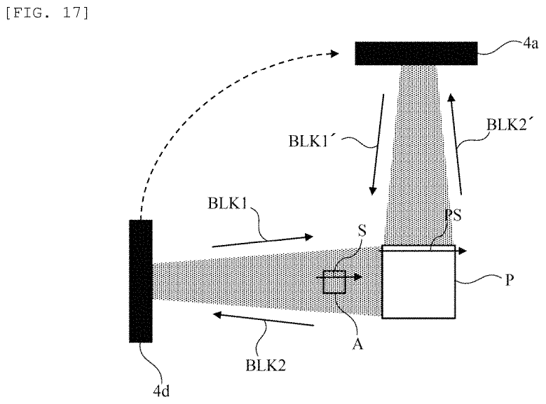

FIG. 18 is a flowchart illustrating an optimization process of the blanking direction in the eighth embodiment. Each of steps in the flowchart of FIG. 18 is executed by the processor 151 executing a program relating to an optimization process of the blanking direction that is stored in the auxiliary storage unit 153.

The computer system 15 acquires the blanking direction, the position of the scanning region A and the position of the previous irradiation region P (Step S1801). Next, the computer system 15 determines whether or not the charged particle beam 2 during blanking in the process of scanning of the previous irradiation region P crosses the scanning region A based on the blanking direction, the position of the scanning region A, and the position of the previous irradiation region P that are acquired (Step S1802). When the computer system 15 determines that the charged particle beam 2 during blanking crosses the scanning region A (Step S1802: Yes), the computer system 15 changes the blanking direction to prevent the charged particle beam 2 during blanking in the process of scanning of the previous irradiation region P from crossing the scanning region A (Step S1803). When the computer system 15 determines that the charged particle beam 2 during blanking in the process of scanning of the previous irradiation region P does not cross the scanning region A (Step S1802: No), the computer system 15 ends the present process without changing the blanking direction in the process of scanning the previous irradiation region P.

The computer system 15 may cause the display unit 156 or another display unit that is communicably connected to the computer system 15 to display characteristic information regarding the blanking direction or the blanking position. The characteristic information includes, for example, a message representing that the charged particle beam 2 during blanking crosses the scanning region and a message urging to change the blanking direction.

### Effect of Eighth Embodiment

In the eighth embodiment, the charged particle beam 2 during blanking in the process of scanning the previous irradiation region P can be prevented from crossing the scanning region A. As a result, charging of the scanning region A or damage of the scanning region A caused by blanking in the process of scanning the previous irradiation region P can be prevented. The other effects are the same as the other embodiments.

### Ninth Embodiment

In the seventh and eighth embodiments, the blanking direction or the blanking position is determined or changed based on the position of the scanning region A and the position of the previous irradiation region P. In a ninth embodiment, the position of the previous irradiation region P is determined without changing the blanking direction.

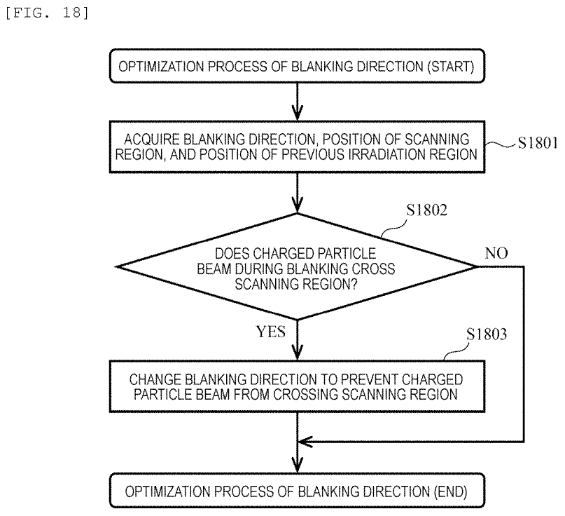

FIGS. 19A and 19B are diagrams illustrating a positional relationship between the previous irradiation region and the scanning region in the ninth embodiment. In the ninth embodiment, the previous irradiation region P is determined to prevent the charged particle beam 2 from crossing the scanning region A during blanking in the process of scanning of the previous irradiation region P. As illustrated in FIG. 19A, for example, when a candidate P3 is selected among candidates P1 to P4 of the previous irradiation region, due to an electric field by the blanking deflector 4, the charged particle beam 2 is deflected in the blanking release direction BLK1 from the retraction region to the candidate P3 of the previous irradiation region. The charged particle beam 2 is deflected to scan the candidate P3 of the previous irradiation region in the scanning direction PS (+X direction) due to an electric field or a magnetic field of the image shift deflector 6. The charged particle beam 2 is deflected in the blanking retraction direction BLK2 from the candidate P3 of the previous irradiation region to the retraction region due to an electric field by the blanking deflector 4. When the charged particle beam 2 is deflected in the blanking release direction BLK1 to the candidate P3 of the previous irradiation region and when the charged particle beam 2 is deflected in the blanking retraction direction BLK2 from the candidate P3 of the previous irradiation region to the retraction region, the charged particle beam 2 crosses the scanning region A1 that is scanned after the candidate P3 of the previous irradiation region. Therefore, the scanning region A that is processed after the candidate P3 of the previous irradiation region is charged.

Accordingly, in the ninth embodiment, as illustrated in FIG. 19B, the candidate P1 of the previous irradiation region is selected as the previous irradiation region to prevent the charged particle beam 2 from crossing the scanning region A during blanking in the process of scanning the previous irradiation region. As long as the charged particle beam 2 during blanking in the process of scanning the previous irradiation region does not cross the scanning region A, the candidate P2 or P4 of the previous irradiation region may be selected as the previous irradiation region. The previous irradiation region P1 is disposed on the retraction region side of blanking further than the scanning region A. Therefore, during blanking in the process of scanning the previous irradiation region P1, the charged particle beam 2 does not cross the scanning region A.

(Determination Process of Previous Irradiation Region)

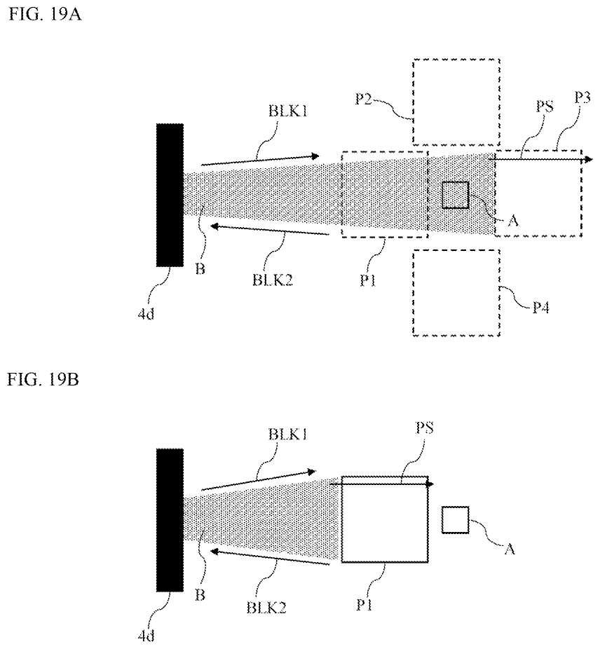

FIG. 20 is a flowchart illustrating a determination process of the previous irradiation region in the ninth embodiment. Each of steps in the flowchart is executed by the processor 151 executing a program relating to the determination process of the previous irradiation region that is stored in the auxiliary storage unit 153.

The computer system 15 acquires the position of the scanning region A and the scanning direction (Step S2001). Next, the computer system 15 determines the position of the previous irradiation region P based on the position of the scanning region A and the scanning direction S (Step S2002).

The computer system 15 may cause the display unit 156 or another display unit that is communicably connected to the computer system 15 to display information regarding the position of the previous irradiation region.

### Effect of Ninth Embodiment

In the ninth embodiment, the position of the previous irradiation region P can be determined based on the position of the scanning region A and the scanning direction PS. Accordingly, the charged particle beam 2 during blanking in the process of scanning the previous irradiation region P at the determined position can be prevented from crossing the scanning region A. As a result, charging of the scanning region A or damage of the scanning region A caused by blanking can be prevented. The other effects are the same as the other embodiments.

### Tenth Embodiment

In the ninth embodiment, the position of the previous irradiation region P is determined based on the position of the scanning region A and the scanning direction PS. On the other hand, In the tenth embodiment, whether or not the charged particle beam 2 crosses the scanning region during blanking in the process of scanning the previous irradiation region is determined to change the position of the previous irradiation region P without changing the blanking direction.

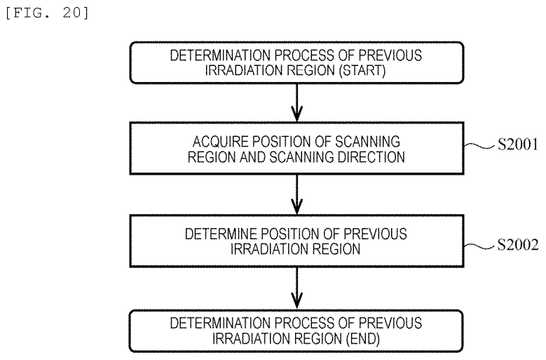

FIGS. 21A and 21B are diagrams illustrating a positional relationship between the previous irradiation region and the scanning region in the tenth embodiment. In the tenth embodiment, whether or not the charged particle beam 2 crosses the scanning region A during blanking in the process of scanning of the previous irradiation region P is determined to change the previous irradiation position. As illustrated in FIG. 21A, due to an electric field by the blanking deflector 4, the charged particle beam 2 is deflected in the blanking release direction BLK1 from the retraction region to the previous irradiation region P3. The charged particle beam 2 is deflected to scan the previous irradiation region P3 in the scanning direction PS (+X direction) due to an electric field or a magnetic field of the image shift deflector 6. The charged particle beam 2 is deflected in the blanking retraction direction BLK2 from the previous irradiation region P3 to the retraction region due to an electric field by the blanking deflector 4.

However, the charged particle beam 2 that is deflected in the blanking release direction BLK1 and the blanking retraction direction BLK2 crosses the scanning region A that is scanned after scanning the previous irradiation region P3. In this case, the scanning region A is charged or damaged by the charged particle beam 2 during blanking. Accordingly, in the tenth embodiment, the position of the previous irradiation region P is changed to prevent the charged particle beam 2 from crossing the scanning region A during blanking in the process of scanning the previous irradiation region P. For example, in the example of FIGS. 21A and 21B, the position of the previous irradiation region is changed from the previous irradiation region P3 to the previous irradiation region P1. That is, in the tenth embodiment, when seen from the retraction region, the previous irradiation region P3 that is disposed more distant than the scanning region A is changed to the previous irradiation region P1 that is disposed close to a scanning region B.

(Optimization Process of Position of Previous Irradiation Region)

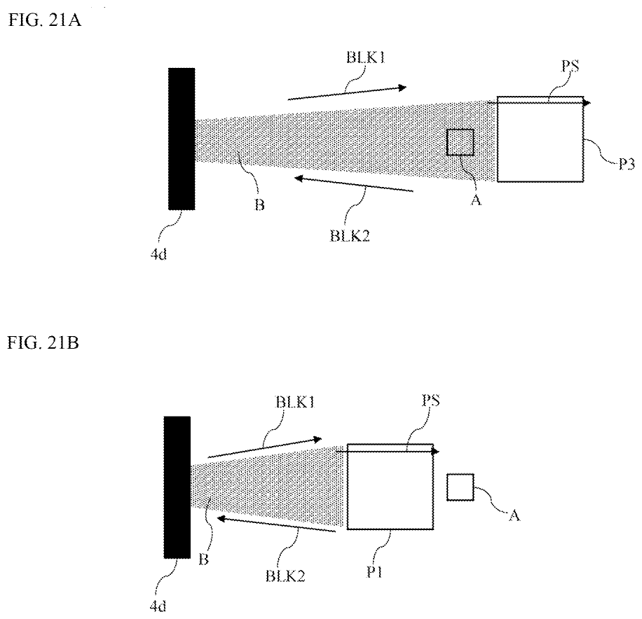

FIG. 22 is a flowchart illustrating an optimization process of the previous irradiation region in the tenth embodiment. Each of steps in the flowchart of FIG. 22 is executed by the processor 151 executing a program relating to the optimization process of the previous irradiation region that is stored in the auxiliary storage unit 153.

The computer system 15 acquires the blanking direction, the position of the scanning region A and the position of the previous irradiation region P (Step S2201). Next, the computer system 15 determines whether or not the charged particle beam 2 during blanking in the process of scanning the previous irradiation region P crosses the scanning region A based on the blanking direction, the position of the scanning region A, and the position of the previous irradiation region P that are acquired (Step S2202). When the computer system 15 determines that the charged particle beam 2 during blanking in the process of scanning the previous irradiation region P crosses the scanning region A (Step S2202: Yes), the computer system 15 changes the position of the previous irradiation region P to prevent the charged particle beam 2 during blanking in the process of scanning the previous irradiation region P from crossing the scanning region A (Step S2203). When the computer system 15 determines that the charged particle beam 2 during blanking in the process of scanning the previous irradiation region P does not cross the scanning region A (Step S2202: No), the computer system 15 ends the present process without changing the position of the previous irradiation region P.

The computer system 15 may cause the display unit 156 or another display unit that is communicably connected to the computer system 15 to display characteristic information regarding the position of the previous irradiation region. The characteristic information includes, for example, a message representing that the charged particle beam 2 during blanking crosses the scanning region and a message urging to change the position of the previous irradiation region.

### Effect of Tenth Embodiment

In the tenth embodiment, the charged particle beam 2 during blanking in the process of scanning the previous irradiation region P can be prevented from crossing the scanning region A. As a result, charging of the scanning region A or damage of the scanning region A caused by blanking in the process of scanning the previous irradiation region P can be prevented. The other effects are the same as the other embodiments.

### Eleventh Embodiment

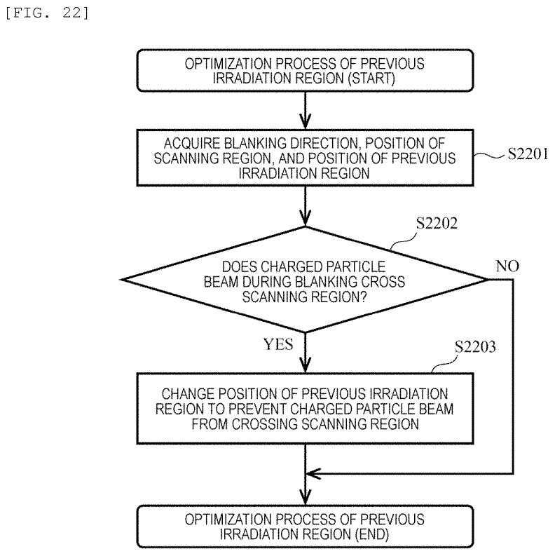

In an eleventh embodiment, an example in which blanking is not performed during the scanning of the previous irradiation region P will be described. FIG. 23 is a flowchart illustrating a process of determining whether or not to perform blanking in the eleventh embodiment. Each of steps in the flowchart of FIG. 23 is executed by the processor 151 executing a program relating to the process of determining whether or not to perform blanking that is stored in the auxiliary storage unit 153.

(Process of Determining Whether or not to Perform Blanking)

As illustrated in FIG. 23, the computer system 15 acquires recipe information (Step S2301). The computer system 15 scans the previous irradiation region P and the scanning region A based on the acquired recipe information. The computer system 15 determines whether or not the previous irradiation region P is to be scanned with the charged particle beam 2 (Step S2302). When the computer system 15 determines that the previous irradiation region P is not to be scanned (Step S2302: No), the computer system 15 performs blanking in the process of scanning the scanning region A (Step S2303). On the other hand, when the computer system 15 determines that the previous irradiation region P is to be scanned (Step S2302: Yes), blanking is not performed in the process of scanning the previous irradiation region P. For example, the charged particle beam 2 scans one scanning line of the previous irradiation region P, and subsequently scans the next scanning line without performing blanking.

When the computer system 15 determines that the previous irradiation region P is to be scanned (Step S2302: Yes), the computer system 15 may turn off the blanking deflector 4. When the computer system 15 determines that the previous irradiation region P is not to be scanned (Step S2302: No), the computer system 15 may turn on the blanking deflector 4.

### Effect of Eleventh Embodiment

In the eleventh embodiment, blanking is not performed in the process of scanning the previous irradiation region P. Thus, the charged particle beam 2 during blanking in the process of scanning the previous irradiation region P can be prevented from crossing the scanning region A. As a result, charging of the scanning region A or damage of the scanning region A caused by blanking can be prevented.

In addition, in the eleventh embodiment, blanking is not performed in the process of scanning the previous irradiation region P. Therefore, the movement of the charged particle beam 2 to the retraction region is prevented. Thus, the scanning time of the previous irradiation region P can be reduced. The other effects are the same as the other embodiments.

### Twelfth Embodiment

In the first to eleventh embodiments, for example, the blanking direction is determined to prevent the charged particle beam during blanking from crossing the scanning region. In a twelfth embodiment, as preliminary charging, the scanning region is irradiated with the charged particle beam during blanking.

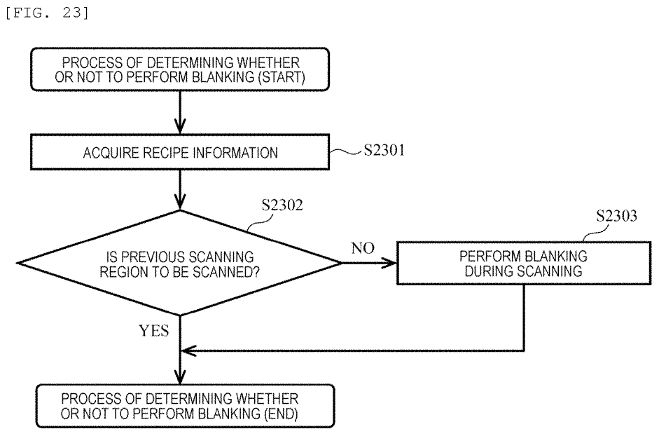

FIG. 24 is a diagram illustrating a relationship between an irradiation time of a sample with a charged particle beam and a charge amount of the sample in the twelfth embodiment. In general, when the sample is irradiated with the charged particle beam, sample charging progresses and is saturated at a given level. As illustrated in FIG. 24, at an irradiation initial stage of the charged particle beam, a change in the charge amount of the sample is significant, and the measurement may be unstable due to image drift or abnormal contrast. Accordingly, in the twelfth embodiment, the charged particle beam is made to cross the scanning region during blanking in the process of scanning the previous irradiation region such that preliminary charging of the scanning region is performed.

(Optimization Process of Blanking Direction)

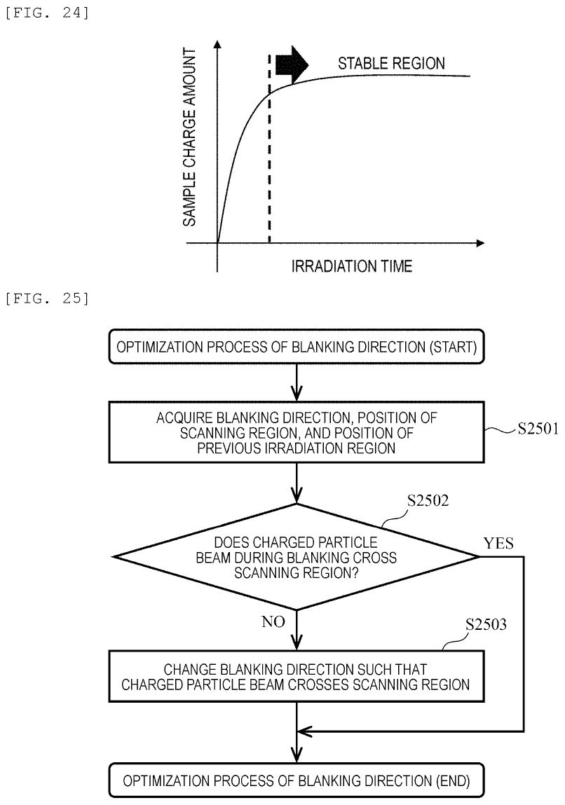

FIG. 25 is a flowchart illustrating an optimization process of the blanking direction in the twelfth embodiment. Each of steps in the flowchart of FIG. 25 is executed by the processor 151 executing a program relating to an optimization process of the blanking direction that is stored in the auxiliary storage unit 153.

The computer system 15 acquires the blanking direction, the position of the scanning region A and the position of the previous irradiation region P (Step S2501). Next, the computer system 15 determines whether or not the charged particle beam 2 during blanking crosses the scanning region A based on the blanking direction, the position of the scanning region A, and the position of the previous irradiation region P that are acquired (Step S2502). When the computer system 15 determines that the charged particle beam 2 during blanking crosses the scanning region A (Step S2502: Yes), the computer system 15 ends the present process without changing the blanking direction. On the other hand, when the computer system 15 determines that the charged particle beam 2 during blanking does not cross the scanning region A (Step S2502: No), the computer system 15 changes the blanking direction such that the charged particle beam 2 during blanking crosses the scanning region A (Step S2503).

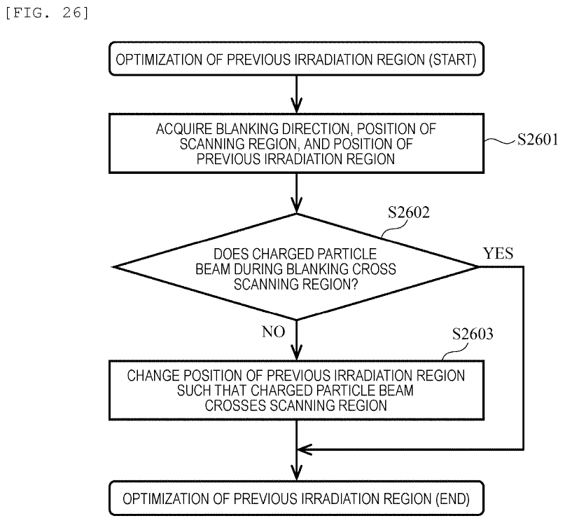

In the flowchart of FIG. 25, the blanking direction is changed such that the charged particle beam 2 during blanking crosses the scanning region A. Instead, the position of the previous irradiation region may be changed. FIG. 26 is a flowchart illustrating an optimization process of the previous irradiation region in the twelfth embodiment. Each of steps in the flowchart of FIG. 26 is executed by the processor 151 executing a program relating to the optimization process of the previous irradiation region that is stored in the auxiliary storage unit 153.

As illustrated in FIG. 26, the computer system 15 executes Steps S2601 and S2602. Since the contents of Steps S2601 and S2602 are the same as the contents of Steps S2501 and S2502 of FIG. 25, the description thereof will not be repeated. The computer system 15 changes the position of the previous irradiation region such that the charged particle beam 2 during blanking crosses the scanning region A (Step S2603).

In addition, in the twelfth embodiment, the blanking direction or the position of the previous irradiation region is changed such that the charged particle beam 2 during blanking crosses the scanning region A. As in the seventh embodiment, the blanking direction may be determined based on the position of the scanning region and the position of the previous irradiation region such that the charged particle beam 2 during blanking crosses the scanning region A. As in the ninth embodiment, the position of the previous irradiation region may be determined based on the position of the scanning region and the scanning direction such that the charged particle beam 2 during blanking crosses the scanning region A.

### Effect of Twelfth Embodiment

In the twelfth embodiment, the scanning region can be preliminarily charged by changing the blanking direction or the blanking position and changing the position of the previous irradiation region such that the charged particle beam during blanking crosses the scanning region. As a result, the processes (observation, length measurement, inspection, analysis, and the like) can be performed in a stable region illustrated in FIG. 24 during the process of the scanning region.

The present disclosure is not limited to the embodiment and includes various modification examples. The embodiments have been described in detail in order to easily describe the present disclosure, and the present disclosure is not necessarily to include all the configurations described above. In addition, a part of the configuration of one embodiment can be replaced with the configuration of another embodiment. Further the configuration of one embodiment can be added to the configuration of another embodiment. In addition, addition, deletion, and replacement of another configuration can also be made for a part of the configuration each of the embodiments.

### REFERENCE SIGNS LIST

1: electron gun
2: charged particle beam
3: convergence lens
4: blanking deflector
4a to 4d: electrode
5: aperture plate
5a: aperture
6: image shift deflector
7: objective lens
8: sample
9: stage
10: secondary electron
11: detector
12: blanking voltage application device
12a to 12d: drive circuit
13: blanking voltage control device
14: convergence lens control device
15: computer system
100: charged particle beam device
151: processor
152: main storage unit
153: auxiliary storage unit
154: input/output I/F
155: communication I/F
156: display unit
157: bus
A, A1 to A12: scanning region
B: blanking irradiation region
C: retraction region
BLK1: blanking release direction
BLK2: blanking retraction direction
BLK3: blanking movement direction
S: scanning direction
T: traveling direction of scanning in scanning region
U: non-scanning region
P, P1 to P4: previous irradiation region
PS: scanning direction of previous irradiation region

1. A charged particle beam device comprising:
a first deflector configured to scan a region of interest with a beam emitted from a beam source;
a second deflector configured to retract the beam to outside of the region of interest after scanning the region of interest with the beam; and
one or more computer systems including one or more processors configured to execute a program stored in a storage medium,
wherein the one or more computer systems
(i) determine a retraction direction or a retraction position of the beam or (ii) output characteristic information regarding the retraction direction or the retraction position of the beam based on a scanning direction of the beam in the region of interest.

2. The charged particle beam device according to claim 1,
wherein the one or more computer systems
determine the retraction direction or the retraction position of the beam to prevent the beam from crossing a non-scanning region in the region of interest during the retraction of the beam.

3. The charged particle beam device according to claim 1,
wherein the one or more computer systems
determine the retraction direction or the retraction position of the beam such that a region other than a non-scanning region in the region of interest is irradiated with the beam during the retraction of the beam.

4. The charged particle beam device according to claim 1,
wherein the one or more computer systems
control the second deflector such that the beam passes outside of the region of interest from the retraction position, is moved to a release position, and is moved from the release position to a start position of next scanning.

5. The charged particle beam device according to claim 1,
wherein the one or more computer systems
control the first deflector such that the beam is deflected for scanning in the scanning direction multiple times in order from the closest to the retraction position of the beam.

6. A charged particle beam device comprising:
a first deflector configured to scan a plurality of regions of interest with a beam emitted from a beam source;
a second deflector configured to retract the beam to outside of the plurality of regions of interest after scanning the regions of interest with the beam; and
one or more computer systems including one or more processors configured to execute a program stored in a storage medium,
wherein the one or more computer systems
(i) determine a processing order of the plurality of regions of interest or (ii) output order information regarding the processing order based on first information regarding positions of the plurality of regions of interest or irradiation positions of the plurality of regions of interest with the beam and second information regarding a retraction position of the beam.

7. The charged particle beam device according to claim 6,
wherein the one or more computer systems
determine the processing order of the plurality of regions of interest to prevent the beam from crossing non-scanning regions in the plurality of regions of interest during the retraction of the beam.

8. The charged particle beam device according to claim 6,
wherein the one or more computer systems
determine the processing order of the plurality of regions of interest such that regions other than non-scanning regions in the plurality of regions of interest are irradiated with the beam during the retraction of the beam.

9. The charged particle beam device according to claim 6,
wherein the one or more computer systems
control the first deflector and the second deflector such that the plurality of regions of interest are processed in the determined processing order while reciprocating the beam between the plurality of regions of interest and the retraction position.

10. The charged particle beam device according to claim 6,
wherein the one or more computer systems
adjust the determined processing order based on a moving distance between the regions of interest.

11. A charged particle beam device comprising:
a first deflector configured to scan a region of interest with a beam emitted from a beam source;
a second deflector configured to retract the beam to outside of the region of interest after scanning the region of interest with the beam; and
one or more computer systems including one or more processors configured to execute a program stored in a storage medium,
wherein the one or more computer systems
(i) determine a retraction direction or a retraction position of the beam in the process of scanning a previous irradiation region that is scanned before the region of interest or (ii) output characteristic information regarding the retraction direction or the retraction position of the beam in the process of scanning the previous irradiation region based on first information regarding a position of the region of interest or an irradiation position of the region of interest with the beam and second information regarding a position of the previous irradiation region.

12. The charged particle beam device according to claim 11,
wherein the one or more computer systems
determine the retraction direction or the retraction position of the beam to prevent the beam from crossing a non-scanning region in the region of interest during the retraction of the beam.

13. The charged particle beam device according to claim 11, wherein the one or more computer systems
determine the retraction direction or the retraction position of the beam such that the beam crosses a non-scanning region in the region of interest during the retraction of the beam.

14. A charged particle beam device comprising:
a first deflector configured to scan a region of interest with a beam emitted from a beam source;
a second deflector configured to retract the beam to outside of the region of interest after scanning the region of interest with the beam; and
one or more computer systems including one or more processors configured to execute a program stored in a storage medium,
wherein the one or more computer systems
(i) determine a position of a previous irradiation region that is scanned before the region of interest or (ii) output characteristic information regarding the position of the previous irradiation region based on first information regarding a position of the region of interest or an irradiation position of the region of interest with the beam and second information regarding a retraction direction or a retraction position of the beam in the process of scanning the previous irradiation region.

15. The charged particle beam device according to claim 14,
wherein the one or more computer systems
determine the position of the previous irradiation region to prevent the beam from crossing a non-scanning region in the region of interest during the retraction of the beam.

16. The charged particle beam device according to claim 14,
wherein the one or more computer systems
determine the position of the previous irradiation region such that the beam crosses a non-scanning region in the region of interest during the retraction of the beam.

17. A charged particle beam device comprising:
a first deflector configured to scan a region of interest and a previous irradiation region with a beam emitted from a beam source;
a second deflector configured to retract the beam to outside of the region of interest after scanning the region of interest with the beam; and
one or more computer systems including one or more processors configured to execute a program stored in a storage medium,
wherein the one or more computer systems
control the first deflector such that the previous irradiation region is scanned and the region of interest is scanned after scanning the previous irradiation region,
do not retract the beam to outside of the region of interest in the process of scanning the previous irradiation region, and
control the second deflector such that the beam is retracted to outside of the region of interest in the process of scanning the region of interest.

18. The charged particle beam device according to claim 17,
wherein the one or more computer systems
turn off the second deflector in the process of scanning the previous irradiation region and turn on the second deflector in the process of scanning the region of interest.
